(19) United States
(12) Patent Application Publication
(10) Pub. No.: US 2008/0264611 A1
(43) Pub. Date: Oct. 30, 2008

(54) Heat plate

(76) Inventors: Kun-Jung Chang, Kaohsiung County (TW); Ching-Yuan Juan, Kaohsiung County (TW); Kuo-Chun Lin, Kaohsiung County (TW)

Correspondence Address: Joe McKinney Muncy, PO Box 1364, Fairfax, VA, 22038-1364, US

(21) Appl. No.: 11/797,050

(22) Filed: Apr. 30, 2007

(51) Int. Cl. H05K 7/20

(52) U.S. Cl. 165/104.26; 165/104.33; 361/700

(57) ABSTRACT

A heat plate mainly includes a hollow body and a plurality of caps. The hollow body is fabricated integrally by aluminum extrusion and has a hollow chamber inside. The hollow chamber has an inner side with a plurality of angular strips formed thereon to enhance heat dissipation efficiency and a plurality of spacing ribs to divide the hollow chamber into a plurality of housing space to hold a liquid to increase the heat dissipation efficiency. The hollow body has one surface with a plurality of sliding tracks formed thereon, a latch flute on the left side and right side to wedge in the sliding tracks of another heat plate to enhance the heat dissipation efficiency. The hollow body has another surface with a PCB circuit formed thereon. Electronic elements may be soldered on the PCB circuit to achieve optimal heat dissipation efficiency.

### FIELD OF THE INVENTION

The present invention relates to a heat plate and particularly to a heat dissipation apparatus formed integrally by aluminum extrusion.

### BACKGROUND OF THE INVENTION

A conventional heat plate consists of radiation fins, a heat conductive duct and a seat. Such a structure has drawbacks when in use, notably:

1. The conventional cooling devices mostly have an air fan to aid heat dispersion. The cooling efficiency relies only the radiation fins is not desirable.

2. The conventional cooling devices have a plurality of elements and heat absorbing blades and conductive ducts that are coupled together to absorb heat. The elements are mostly made from plastics that cannot transfer heat among them. Relying only the heat absorbing blades and conductive ducts in the seat to transfer heat is not fast enough.

3. The conventional heat absorbing blades are mostly made of solid blade material such as copper. The heat absorbing blades do not provide desired heat energy circulation to disperse the heat which is being continuously generated. Hence the cooling speed is limited.

### SUMMARY OF THE INVENTION

The primary object of the present invention is to provide a heat plate that has a high heat dissipation efficiency and can be configured to meet individual user's requirement.

To achieve the foregoing object the heat plate according to the -invention mainly includes a hollow body and a plurality of caps. The hollow body is fabricated integrally by aluminum extrusion and has a hollow chamber with a plurality of angular strips formed on an inner side to increase heat dissipation efficiency and a plurality of spacing ribs to divide the hollow chamber into a plurality of housing spaces that communicate with one another. Thereby a liquid capable of enhancing heat dissipation efficiency can be held inside. The hollow chamber further has a plurality of sliding tracks on one surface and latch flutes on the left side and right side to allow a plurality of the heat plates to be wedged in and connected to one another to boost heat dissipation efficiency. The heat plate has another surface which may be printed with a PCB circuit. Electronic elements may be soldered on the surface where the PCB is located to achieve optimal heat dissipation efficiency.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of the invention.

FIG. 2A is a perspective view of the invention.

FIG. 2B is a cross section taken on line 2B-2B in FIG. 2A.

FIG. 3 is a schematic view of the invention in a coupling condition.

FIG. 4 is a perspective view of the invention in a coupled condition.

FIG. 5 is a side view of the invention in a coupled condition.

FIG. 6 is a perspective view of the heat plate of the invention in a mutually coupling condition.

FIG. 7 is a perspective view of the heat plate of the invention in a mutually coupled condition.

FIG. 8 is a side view of the heat plate of the invention in a mutually coupled condition.

FIG. 9 is a perspective view of the heat plate of the invention with one surface printed with a PCB circuit.

FIG. 10 is a perspective view of the heat plate of the invention with electronic elements mounted onto the PCB circuit.

FIG. 11 is an exploded view of another embodiment of the invention.

FIG. 12 A is a perspective of another embodiment of the invention.

FIG. 12B is a cross section taken on line 12B-12B in FIG. 12A.

FIG. 13 is a perspective view of another embodiment of the invention in a coupling condition.

FIG. 14A is perspective view of another embodiment of the invention in a coupled condition.

FIG. 14B is a cross section taken on line 14B-14B in FIG. 14A.

FIG. 15 is a perspective view of another embodiment of the heat plate of the invention with one surface printed with a PCB circuit.

FIG. 16 is a perspective view of another embodiment of the heat plate of the invention in a mutually coupled condition.

FIG. 17 is a perspective view of yet another embodiment of the heat plate of the invention with an aluminum duct located on the cap.

FIG. 18 is a schematic view of yet another embodiment of the heat plate of the invention with an aluminum duct bent after vacuumed.

FIG. 19 is a perspective view of the heat plate of the invention with an aluminum duct located on the cap.

FIG. 20 is a schematic view of the heat plate of the invention with an aluminum duct bent after vacuumed.

FIG. 21 is an exploded view of yet another embodiment of the invention in a coupling condition.

FIG. 22A is a perspective view of yet another embodiment of the invention in a coupled condition.

FIG. 22B is a cross section taken on line 22A-22A in FIG. 22A.

### DETAILED DESCRIPTION OF THE PREFERRED EMBODIMENTS

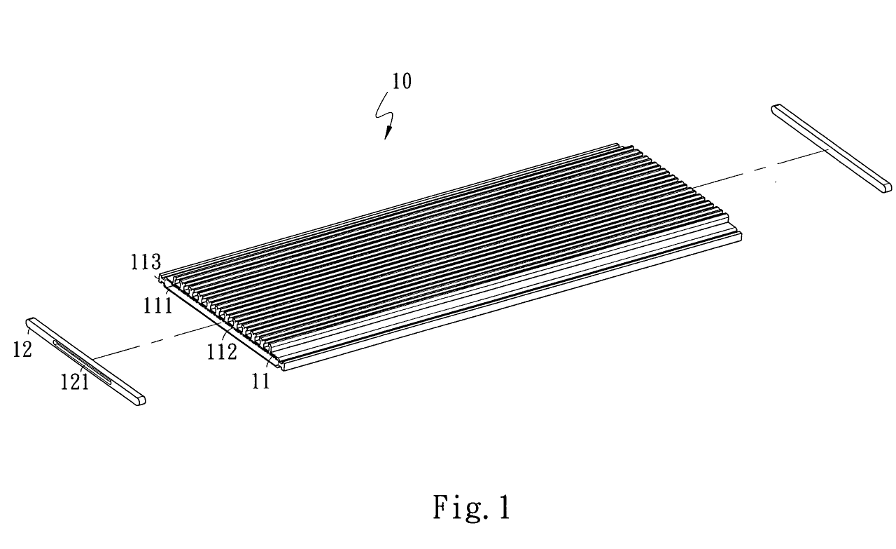

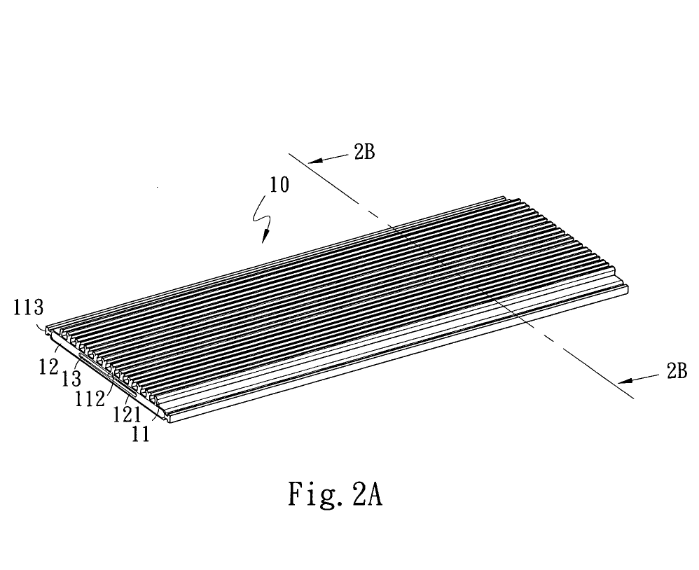

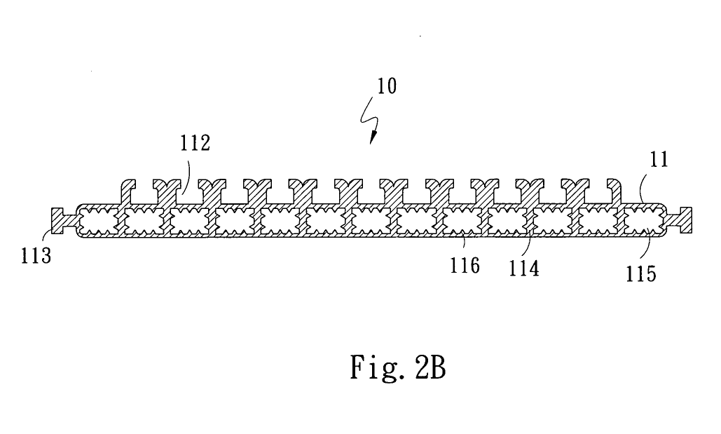

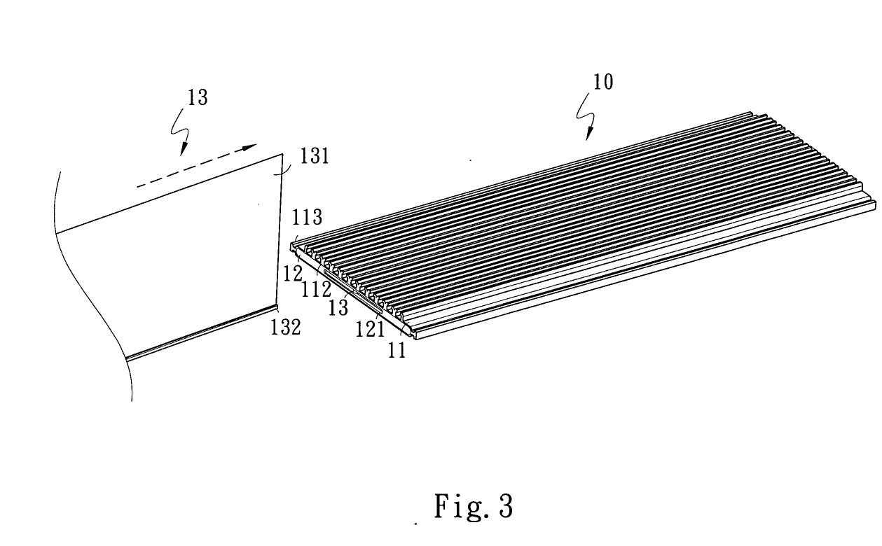

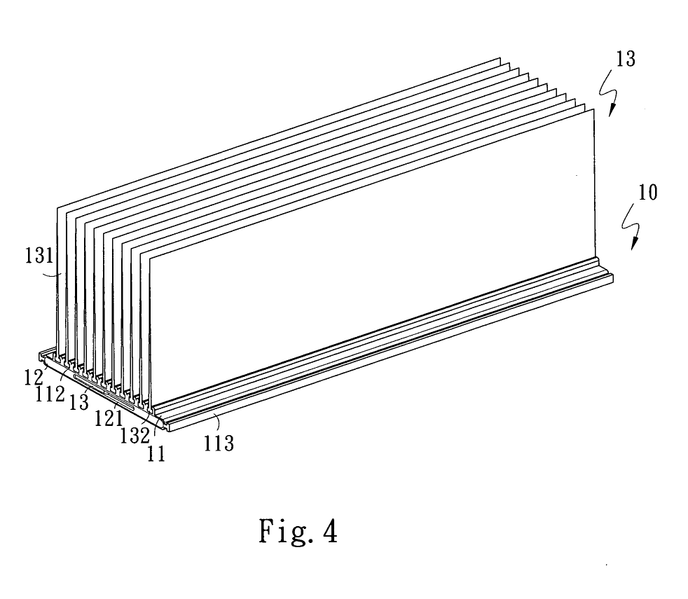

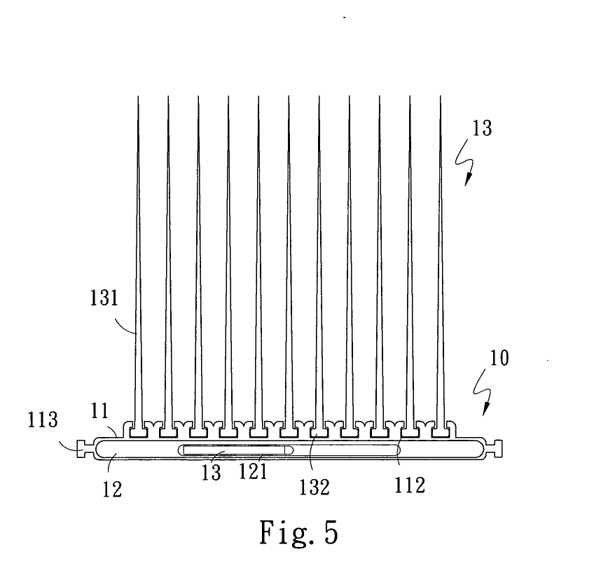

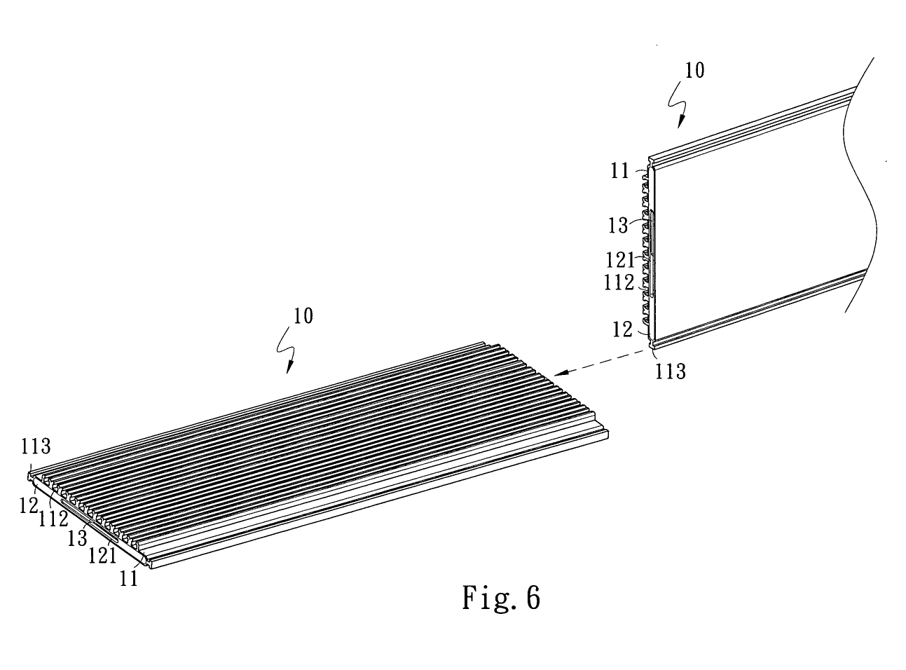

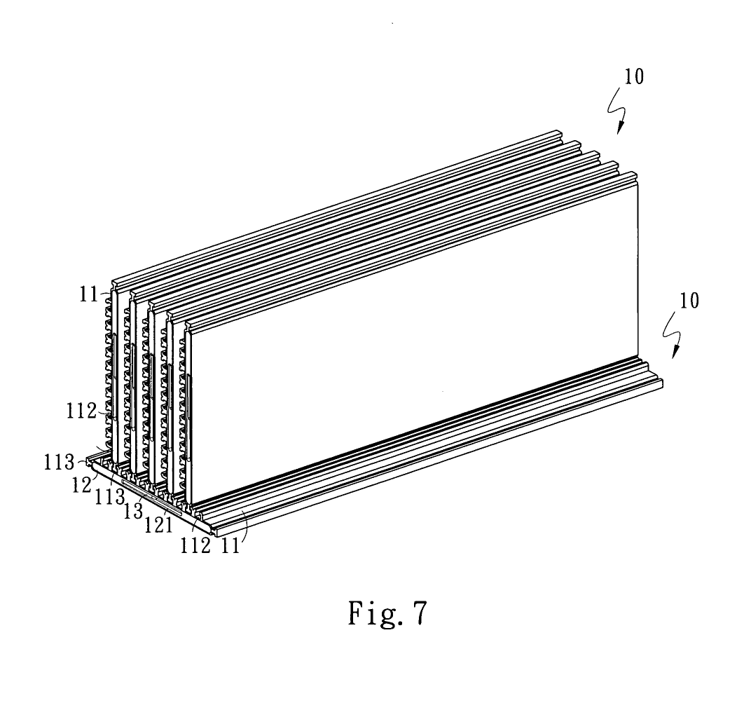

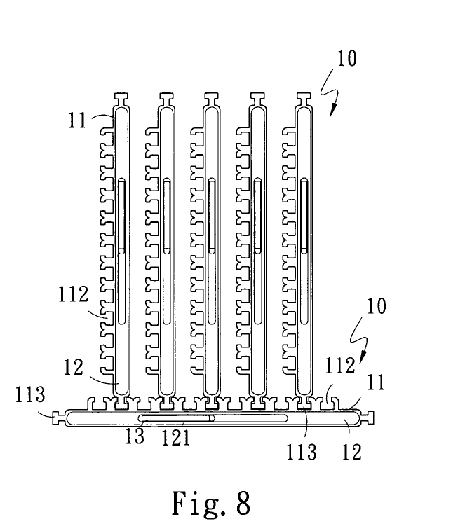

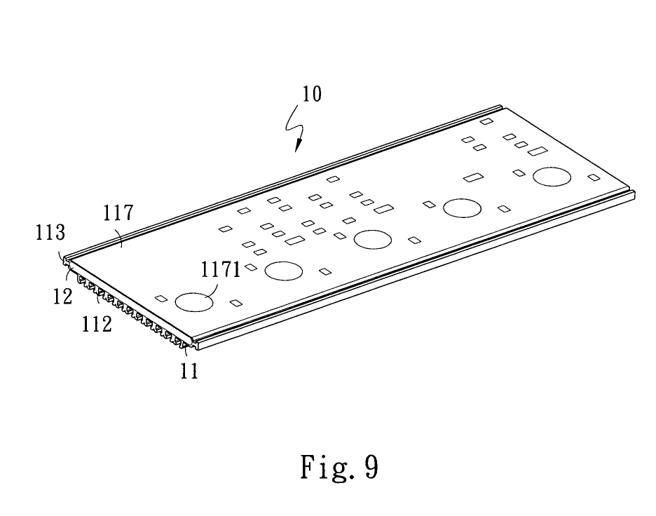

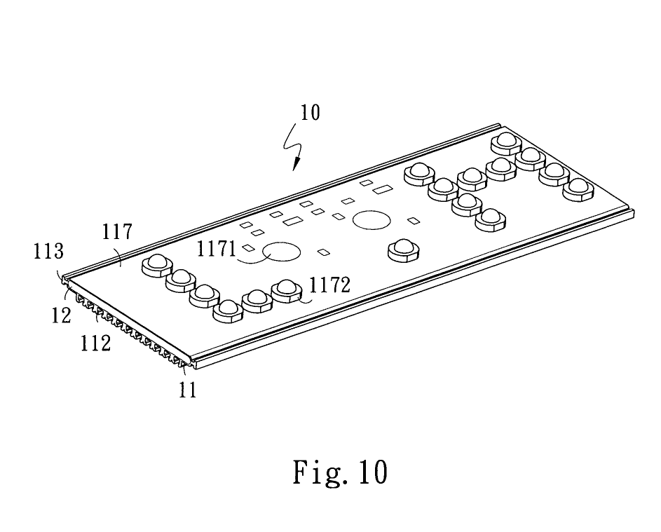

Please refer to FIGS. 1, 2A and 2B, the heat plate 10 according to the invention mainly includes a hollow body 11, a plurality of radiation fins 13 and a plurality of caps 12. The hollow body 11 is fabricated integrally by aluminum extrusion. It has a hollow chamber 111 inside. The hollow chamber 111 has an inner side which has a plurality of angular strips 116 formed thereon to increase heat dissipation efficiency. The hollow chamber 111 also is divided by a plurality of spacing ribs 114 to form a plurality of housing spaces 115 that communicate with one another and hold a liquid to enhance heat dissipation efficiency. On one surface of the hollow body 11 there are a plurality of sliding tracks 112 and a left latch flute 113 on the left side and right side. Referring to FIGS. 3, 4 and 5, each of the radiation fins 13 has a radiation portion 131 and a latch seat 132 at one end to be wedged in the sliding tracks 112 to increase heat dissipation efficiency of the heat plate 10. The cap 12 has a trough 121. Referring to FIGS. 6, 7 and 8, a plurality of heat plates 10 may also be wedged in the sliding tracks 112 on one surface of another heat plate 10 to couple the heat plates 10 together to further increase heat dissipation efficiency. Referring to FIGS. 9 and 10, the heat plate 10 has another surface 117 which may have a PCB circuit 1171 printed thereon. Electronic elements 1172 may be soldered on the PCB circuit 1171 to achieve optimal heat dissipation efficiency.

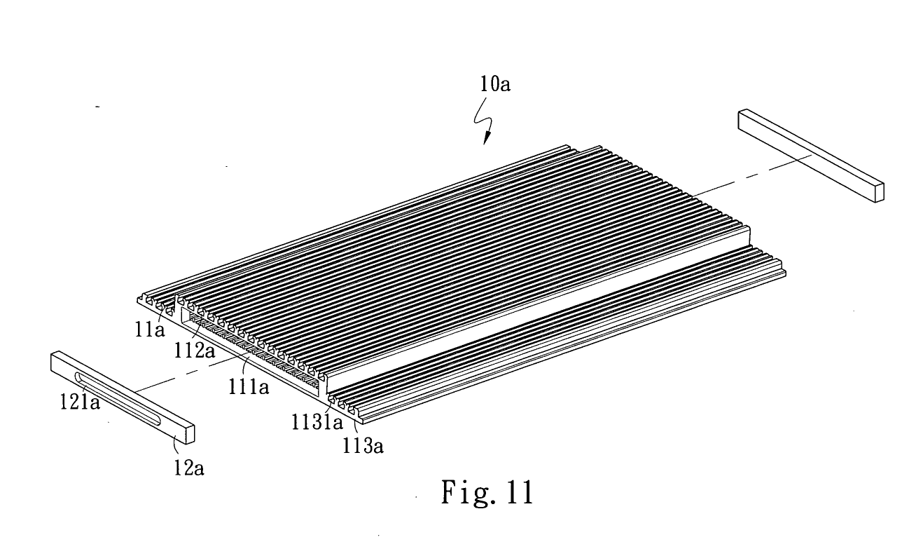

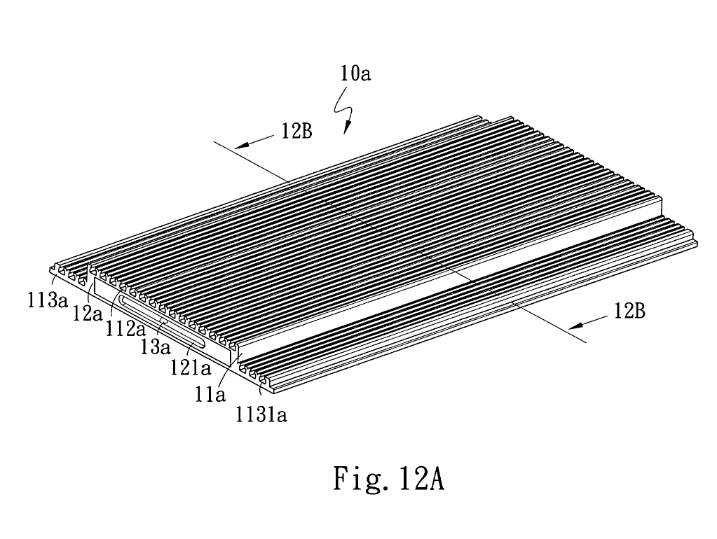

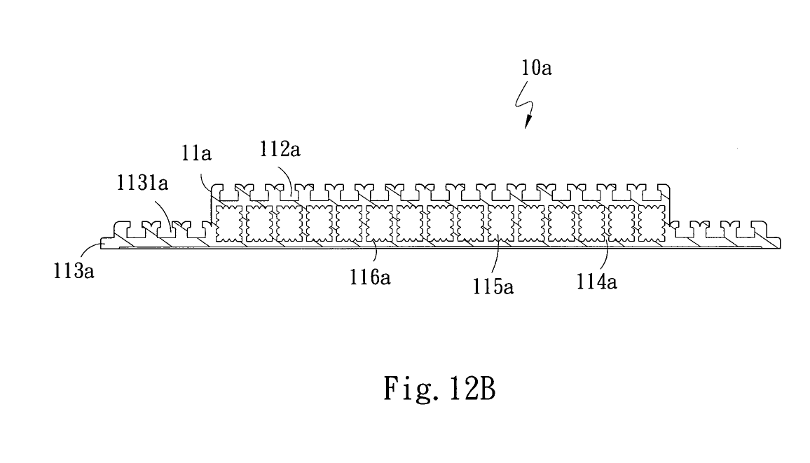

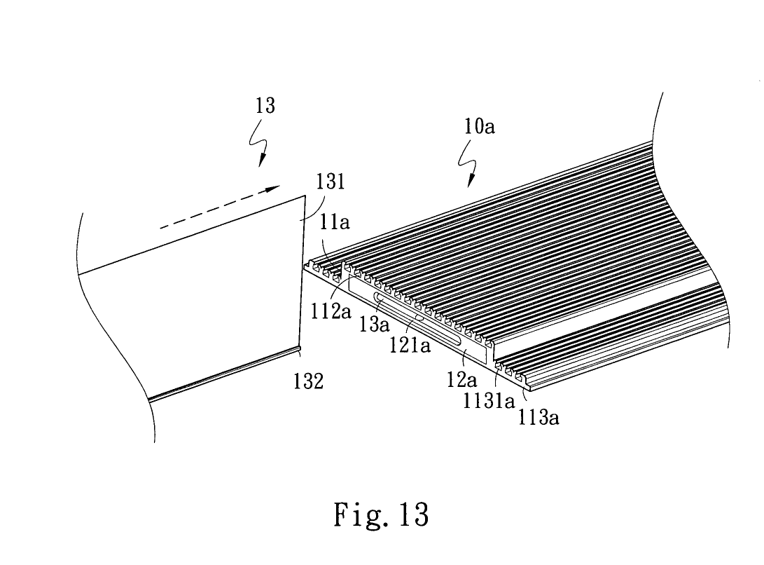

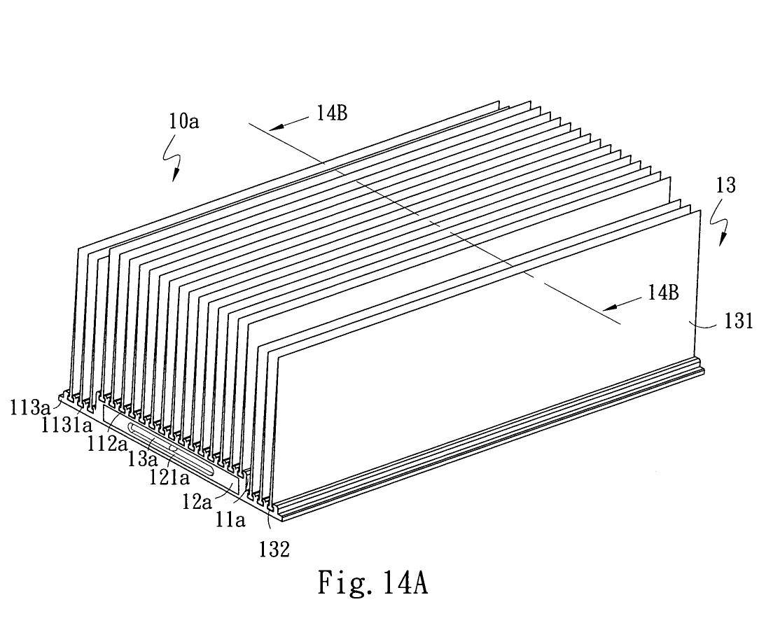

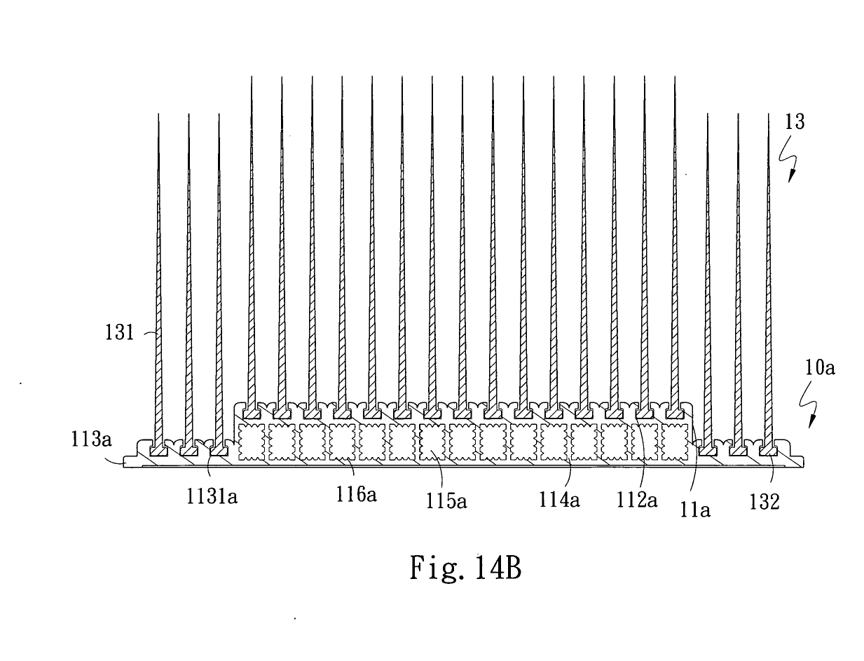

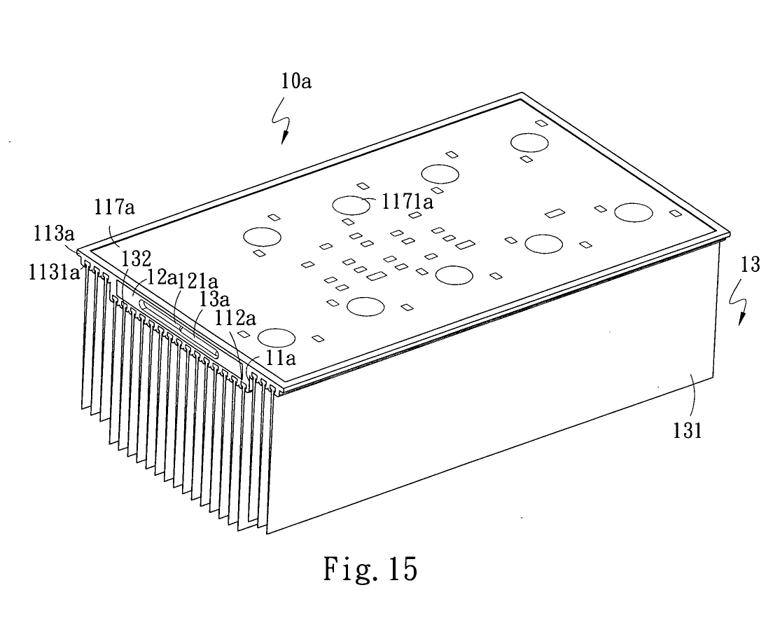

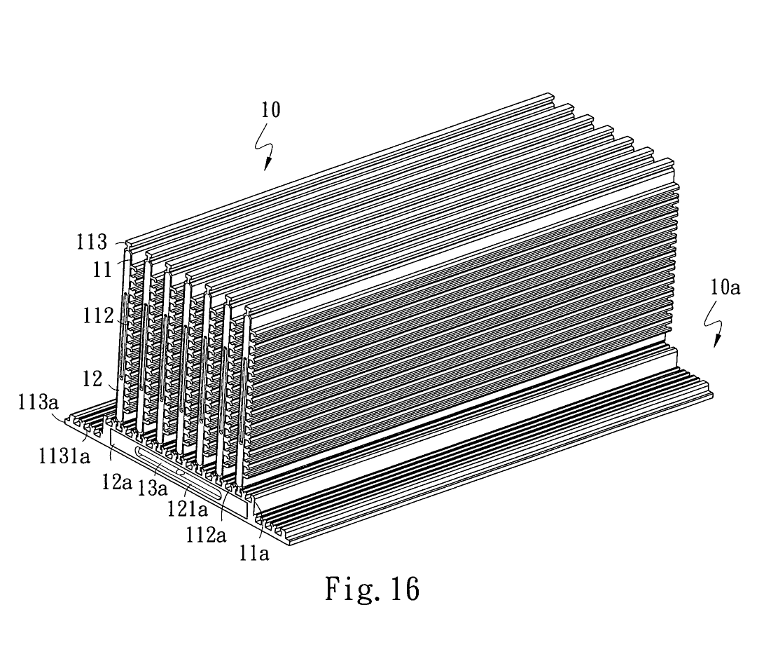

Refer to FIGS. 11, 12A and 12B for another embodiment of the heat plate 10a of the invention. On the left side and right side of a hollow body 11a there is a plane portion 113a. The plane portion 113a also has sliding tracks 1131a formed that on same as the sliding tracks 112a formed on the hollow body 11a as shown in FIG. 16 to be wedged in by other heat plates 10 to increase the contact area with the air to improve heat dissipation efficiency. The another embodiment of the heat plate 10a also includes a hollow body 11a, a plurality of radiation fins 13a and a plurality of caps 12a. The hollow body 11a is fabricated integrally by aluminum extrusion. It has a hollow chamber 11a inside. The hollow chamber 11a has an inner side which has a plurality of angular strips 116a formed thereon to increase heat dissipation efficiency. The hollow chamber 111a also is divided by a plurality of spacing ribs 114a to form a plurality of housing spaces 115a that communicate with one another and hold a liquid to enhance heat dissipation efficiency. On one surface of the hollow body 11a there is a plurality of sliding tracks 112a to be wedged in by the latch seat 132 of other radiation fins 13. The cap 12a also has a trough 121 a as shown in FIGS. 13, 14A and 14B. The hollow body further has another surface 117a to be printed with a PCB circuit 1171a as shown in FIG. 15.

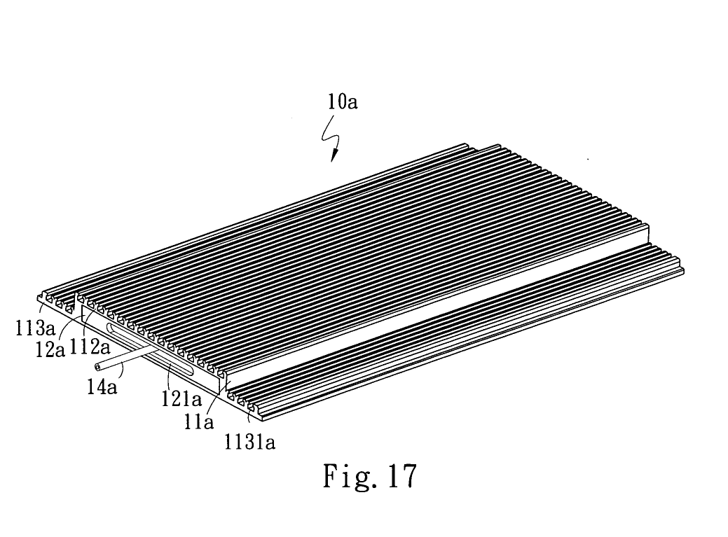

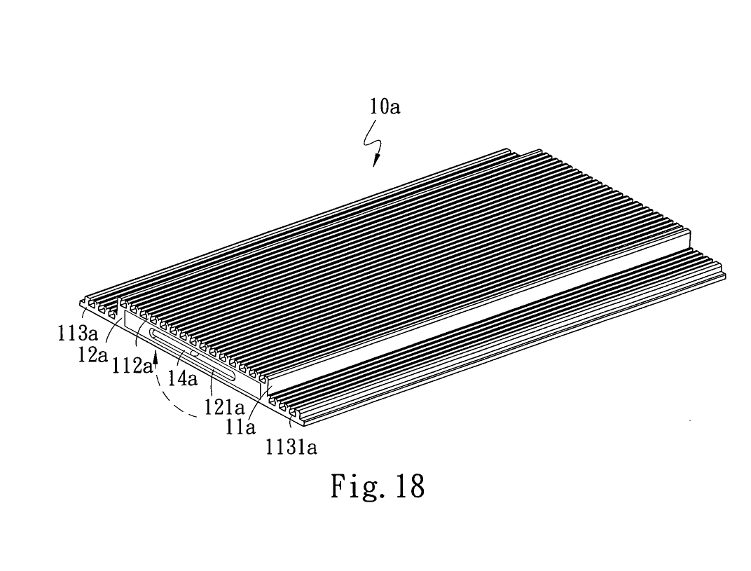

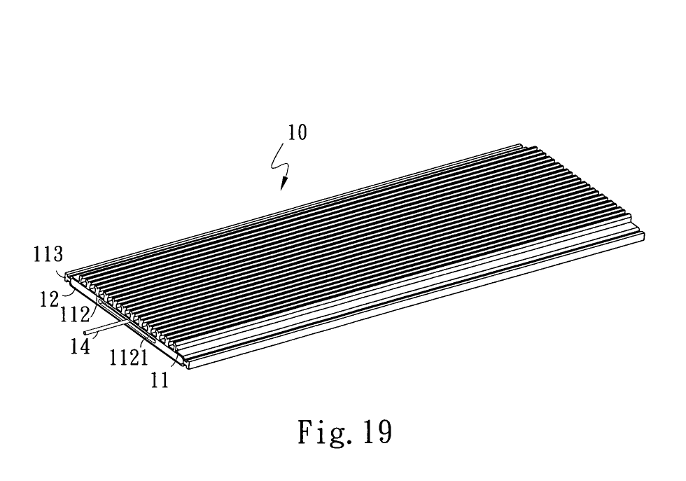

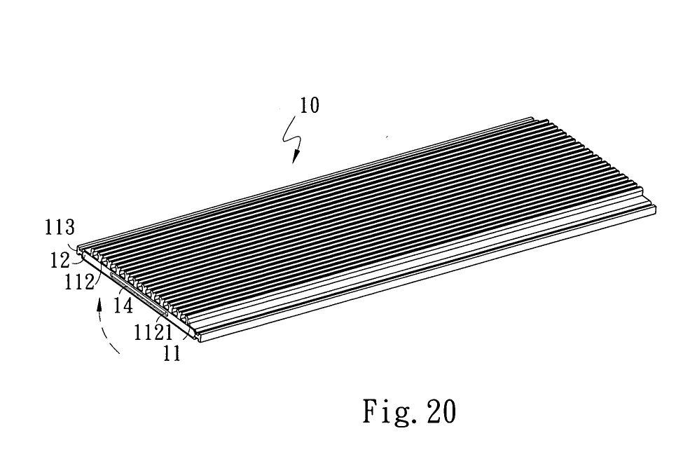

Refer to FIGS. 17 and 18 for yet another embodiment of the heat plate 10a of the invention in which a liquid is to be filled inside to increase heat dissipation efficiency. First the hollow chamber 111a has to be vacuumed. To accomplish this, an aluminum duct 14a is disposed in a trough 121a of the cap 12a to suck the air from hollow chamber 11a. After vacuumed, the opening of the aluminum duct 14a is sealed to prevent air from entering. Then the aluminum duct 14a is bent in the trough 121a. Thus not only the hollow chamber 111a is vacuumed, but the profile can be maintained intact. Such an approach may also be applied to the heat plate 10 as shown in FIGS. 19 and 20. In the trough 121 of the cap 12, the aluminum duct 14 depicted in yet another embodiment is disposed inside to achieve the same effect.

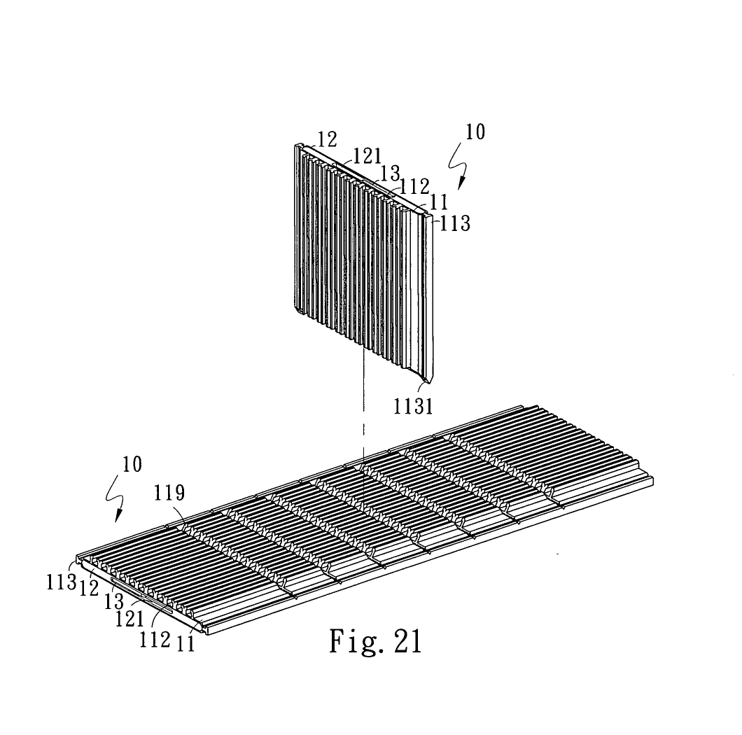

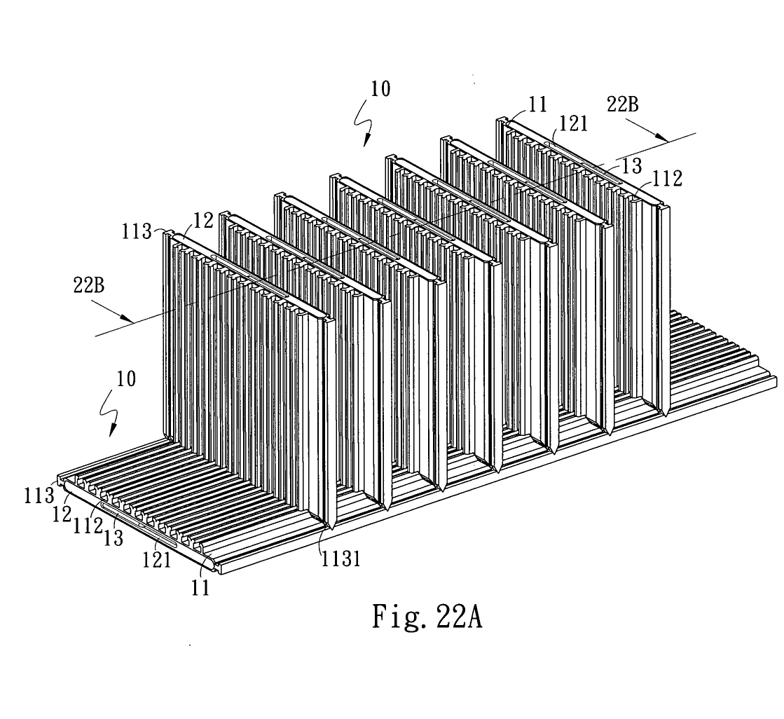

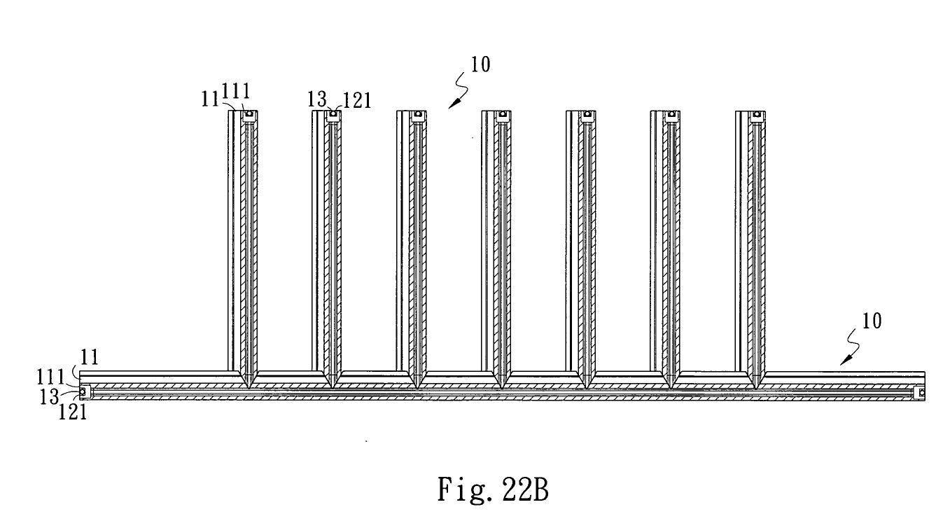

The heat plate 10 of the invention may also be arranged in a juxtaposed or wedged fashion to enhance heat dissipation efficiency. Referring to FIGS. 21 and 22A, first a groove 119 is formed on the hollow body 11 at a depth to hold the hollow chamber 111. A plurality of the heat plates 10 with a ridge 1131 formed at one side of the hollow body 111 corresponding to the groove 119. Then wedge the ridge in the groove 119 and perform soldering thereon as shown in FIG. 22B to allow the hollow chambers 111 to communicate with one another. Such a structure can improve heat dissipation efficiency.

What is claimed is:

1. A heat plate comprising a hollow body, a plurality of radiation fins and a plurality of caps, wherein:
the hollow body is fabricated integrally by aluminum extrusion and has a hollow chamber which has an inner side formed with a plurality of angular strips and a plurality of spacing ribs to divide the hollow chamber into a plurality of housing spaces that communicate with one another and hold a liquid to enhance heat dissipation efficiency, the hollow body further having one surface which has a plurality of sliding tracks formed thereon and another surface which has a PCB circuit formed thereon, and a latch flute formed respectively on a left side and a right side thereof;
each of the radiation fins has a radiation portion and a latch seat at one end mating the latch flute for wedging the radiation fins in the sliding tracks; and
the cap has a trough formed on one side.

2. The heat plate of claim 1, wherein the hollow body has a plane portion on the left side and the right side thereof, the plane portion having sliding tracks formed thereon same as the ones on the hollow body to be wedged in by other heat plates to increase contact area with air to enhance heat dissipation efficiency.

3. The heat plate of claim 1, wherein the hollow body has another surface which has a PCB circuit formed thereon.

4. The heat plate of claim 1, wherein the heat plate is arranged in a juxtaposed fashion and coupled with another to enhance heat dissipation efficiency.

5. The heat plate of claim 1, wherein a plurality of the heat plates can be soldered on one heat plate to allow the hollow chamber of each hollow body to communicate with one another.

6. The heat plate of claim 1, wherein the trough of the cap holds an aluminum duct to vacuum the hollow chamber, the aluminum duct being bent and held in the trough after the hollow chamber has been vacuumed.
